(19) United States
(12) Patent Application Publication
(10) Pub. No.: US 2026/0162583 A1
(43) Pub. Date: Jun. 11, 2026

(54) DISPLAY PANEL AND DISPLAY DEVICE INCLUDING THE SAME

(71) Applicant: LG DISPLAY CO., LTD., Seoul (KR)

(72) Inventors: Jae Hoon PARK, Paju-si (KR); Gyu Bin YU, Paju-si (KR); Hun Ki SHIN, Paju-si (KR)

(73) Assignee: LG DISPLAY CO., LTD., Seoul (KR)

(21) Appl. No.: 19/337,329

(22) Filed: Sep. 23, 2025

(30) Foreign Application Priority Data
Dec. 11, 2024 (KR) 10-2024-0183253

(51) Int. Cl. G09G 3/20; G09G 3/3233

(52) U.S. Cl. CPC G09G 3/2074; G09G 3/3233; G09G 2300/0413; G09G 2300/0452; G09G 2300/0819; G09G 2300/0852; G09G 2320/0242; G09G 2320/0247; G09G 2330/021; G09G 2330/10; G09G 2340/0435

(57) ABSTRACT

A display panel and a display device including the same are discussed. The display panel includes a first sub-pixel including a first pixel circuit configured to drive a first light-emitting element, a second sub-pixel including a second pixel circuit configured to drive a second light-emitting element, a third sub-pixel including a third pixel circuit configured to drive a third light-emitting element, and a compensation capacitor connected to an anode electrode of one or more of the first light-emitting element, the second light-emitting element, and the third light-emitting element.

### CROSS-REFERENCE TO RELATED APPLICATION

This application claims priority to and the benefit of Korean Patent Application No. 10-2024-0183253, filed in the Republic of Korea on Dec. 11, 2024, the disclosure of which is incorporated herein by reference in its entirety.

### BACKGROUND

### Field

The present disclosure relates to a display panel and a display device including the same.

### Discussion of the Related Art

An electroluminescent display device includes self-emissive light-emitting elements, for example, organic light emitting diodes (OLEDs), which are arranged in respective sub-pixels, and has advantages of fast response speed, high luminous efficiency, high luminance, and a wide viewing angle. The electroluminescent display device not only has a fast response speed and excellent luminous efficiency, luminance, and viewing angle, but also can represent black gradation as complete black, and thus has excellent contrast ratio and color reproduction rate. Such an electroluminescent display device does not require a backlight unit and can be implemented on a plastic substrate, a thin glass substrate, and a metal substrate that are flexible materials.

Each of the pixels of an electroluminescence display includes a pixel circuit for driving an OLED. A turn-on time of an OLED by color at a low grayscale is different according to the structures of the pixel circuit and the OLED, and improvement of image quality at the low grayscale is needed.

### SUMMARY OF THE DISCLOSURE

An object of the present disclosure is to solve or address the above-described and other necessity and/or problems associated with the related art.

The present disclosure provides a display panel capable of improving image quality, and a display device including the same.

The objectives of the present disclosure are not limited to those described above, and other objectives not explicitly mentioned will be clearly understood by those skilled in the art from the following description.

A display panel according to one embodiment of the present disclosure includes: a first sub-pixel including a first pixel circuit configured to drive a first light-emitting element; a second sub-pixel including a second pixel circuit configured to drive a second light-emitting element; a third sub-pixel including a third pixel circuit configured to drive a third light-emitting element; and at least one compensation capacitor connected to an anode electrode of one or more of the first light-emitting element, the second light-emitting element, and the third light-emitting element. The first light-emitting element, the second light-emitting element, and the third light-emitting element emit light of different wavelengths.

The at least one compensation capacitor can include: a first compensation capacitor connected between the anode electrode of the first light-emitting element and a constant voltage node; a second compensation capacitor connected between the anode electrode of the second light-emitting element and the constant voltage node; and a third compensation capacitor connected between the anode electrode of the third light-emitting element and the constant voltage node. The capacitance of the first compensation capacitor can be greater than a capacitance of each of the second compensation capacitor and the third compensation capacitor. The first light-emitting element can emit red light. The second light-emitting element can emit green light. The third light-emitting element can emit blue light.

The first compensation capacitor, the second compensation capacitor, and the third compensation capacitor can be connected in common to a single power line that crosses the first sub-pixel, the second sub-pixel, and the third sub-pixel. A constant voltage is applied to the single power line.

The capacitance of the third compensation capacitor can be greater than the capacitance of the second compensation capacitor.

The at least one compensation capacitor can include: a first compensation capacitor connected between the anode electrode of the first light-emitting element and a constant voltage node; and a second compensation capacitor connected between the anode electrode of the third light-emitting element and the constant voltage node. A capacitance of the first compensation capacitor is greater than a capacitance of the second compensation capacitor. The first light-emitting element can emit red light. The second light-emitting element can emit green light. The third light-emitting element can emit blue light.

The at least one compensation capacitor can include a compensation capacitor connected between the anode electrode of the first light-emitting element and a constant voltage node. The first light-emitting element can emit red light. The second light-emitting element can emit green light. The third light-emitting element can emit blue light.

A constant voltage can be applied to the constant voltage node. Each of the first light-emitting element, the second light-emitting element, and the third light-emitting element can include a capacitor. A capacitance of the compensation capacitor is smaller than a capacitance of the capacitor of each of the first light-emitting element, the second light-emitting element, and the third light-emitting element.

Each of the first pixel circuit, the second pixel circuit, and the third pixel circuit can include: a driving transistor including a gate electrode connected to a first node, a first electrode connected to a second node, and a second electrode connected to a third node; and a storage capacitor connected between a constant voltage node to which a pixel driving voltage is applied and the first node. Each of the first light-emitting element, the second light-emitting element, and the third light-emitting element can includes a capacitor. Each of the capacitance of the compensation capacitor and a capacitance of the storage capacitor can be smaller than a capacitance of the capacitor of each of the first light-emitting element, the second light-emitting element, and the third light-emitting element.

Each of the first pixel circuit, the second pixel circuit, and the third pixel circuit can further include: a first switch transistor that is connected between a data line to which a data voltage is applied and the second node and electrically connects the data line to the second node when turned on in response to a second scan signal; a second switch transistor that is connected between the second node and a first power line to which an on bias voltage is applied and applies the on bias voltage to the second node when turned on in response to a third scan signal; a third switch transistor that is connected between a fourth node to which the anode electrode of the light-emitting element is connected and a second power line to which an anode reset voltage is applied and applies the anode reset voltage to the fourth node when turned on in response to the third scan signal; a fourth switch transistor that is connected between the first node and a fifth power line to which an initialization voltage is applied and applies the initialization voltage to the first node when turned on in response to a fourth scan signal; a fifth switch transistor that is connected between the first node and the third node and electrically connects the first node to the third node when turned on in response to a first scan signal; a sixth switch transistor that is connected between a third power line to which the pixel driving voltage is applied and the second node and applies the pixel driving voltage to the second node when turned on in response to a light emission signal; and a seventh switch transistor that is connected between the third node and the fourth node and electrically connects the third node to the fourth node when turned on in response to the light emission signal. The anode electrode of the light-emitting element corresponding to the fourth node can be connected to one electrode of the compensation capacitor. A pixel ground voltage can be applied to a cathode electrode of the light-emitting element. The other electrode of the compensation capacitor can be connected to the second power line. The storage capacitor can be connected between the third power line and the first node.

The display panel can further include: a dummy pixel that is provided in a non-display area and includes a pixel circuit; and a repair line that connects the fourth node of a defective sub-pixel among the first sub-pixel, the second sub-pixel, and the third sub-pixel to the pixel circuit of the dummy pixel. The fourth node of the defective sub-pixel can be disconnected. The first sub-pixel, the second sub-pixel, and the third sub-pixel can be provided in a display area where an image is displayed.

A display device according to one embodiment of the present disclosure includes: a display panel including a plurality of data lines, a plurality of dummy data lines, a plurality of gate lines intersecting the data lines and the dummy data lines, a plurality of power lines, a plurality of pixels, a plurality of dummy pixels, at least one compensation capacitor, and a gate driving circuit connected to the gate lines; and a data driving circuit connected to the data line and the dummy data line. Each of the pixels includes: a first sub-pixel including a first pixel circuit configured to drive a first light-emitting element; a second sub-pixel including a second pixel circuit configured to drive a second light-emitting element; a third sub-pixel including a third pixel circuit configured to drive a third light-emitting element. The first light-emitting element, the second light-emitting element, and the third light-emitting element emit light of different wavelengths. The at least one compensation capacitor is connected to an anode electrode of one or more of the first light-emitting element, the second light-emitting element, and the third light-emitting element,

According to the embodiments of the present disclosure, it is possible to reduce power consumption without causing deterioration of image quality. Further, the at least one compensation capacitor is additionally connected to the anode electrode of the light-emitting element with a capacitor having a small capacitance to make the charging characteristics of the light-emitting elements configured to emit light of different colors similar, and as a result, it is possible to improve image quality, in particular, image quality at the low grayscale.

The effects of the present disclosure are not limited to the effects described above, and other effects not described will be understood by those skilled in the art from the following description and the appended claims.

### BRIEF DESCRIPTION OF THE DRAWINGS

The above and other objects, features, and advantages of the present disclosure will become more apparent to those of ordinary skill in the art by describing embodiments of the present disclosure thereof in detail with reference to the attached drawings, in which:

FIG. 1 is a block diagram illustrating a display device according to an embodiment of the present disclosure;

FIG. 2 is a plan view illustrating a planar arrangement of gate drivers according to the embodiment of the present disclosure;

FIG. 3 is a circuit diagram illustrating sub-pixels according to the embodiment of the present disclosure;

FIGS. 4A to 4C are diagrams illustrating various examples where a compensation capacitor is connected to a power line to which an anode reset voltage is applied according to examples of the present disclosure;

FIGS. 5A and 5B are diagrams illustrating patterns of power lines provided in a display panel according to aspects of the present disclosure;

FIG. 6 is a circuit diagram illustrating a pixel circuit according to the embodiment of the present disclosure;

FIG. 7 is a cross-sectional view illustrating a cross-sectional structure of a pixel according to the embodiment of the present disclosure;

FIG. 8 is a plan view illustrating a part of a planar arrangement structure of a sub-pixel according to the embodiment of the present disclosure;

FIG. 9 is a cross-sectional view of the display panel taken along line I-I′ in FIG. 8; and

FIG. 10 is a circuit diagram illustrating an example where a defective sub-pixel is connected to a dummy pixel and is normally driven.

### DETAILED DESCRIPTION OF THE EMBODIMENTS

The advantages and features of the present disclosure and methods for accomplishing the same will be more clearly understood from embodiments described below with reference to the accompanying drawings. However, the present disclosure is not limited to the following embodiments but can be implemented in various different forms. Rather, the present embodiments will make the disclosure of the present disclosure complete and allow those skilled in the art to completely comprehend the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the present specification. Further, in describing the present disclosure, detailed descriptions of known related technologies can be omitted to avoid unnecessarily obscuring the subject matter of the present disclosure.

The terms such as “comprising,” “including,” “having,” and “consist of” used herein are generally intended to allow other components to be added unless the terms are used with the term “only.” Any references to singular can include plural unless expressly stated otherwise.

Components are interpreted to include an ordinary error range even if not expressly stated.

When a positional or interconnected relationship is described between two components, such as “on top of,” “above,” “below,” “next to,” “connect or couple with,” “crossing,” “intersecting,” or the like, one or more other components can be interposed between them, unless “immediately” or “directly” is used.

When a temporal antecedent relationship is described, such as “after”, “following”, “next to”, “before”, or the like, it may not be continuous on a time base unless “immediately” or “directly” is used.

The terms “first,” “second,” and the like can be used to distinguish elements from each other, but the functions or structures of the components are not limited by ordinal numbers or component names in front of the components. Further, the term “can” fully encompasses all the meanings and coverages of the term “may” and vice versa.

The following embodiments can be partially or entirely bonded to or combined with each other and can be linked and operated in technically various ways. The embodiments can be carried out independently of or in association with each other.

The pixel circuit and the gate drive circuit of the display device can include a plurality of transistors. The transistor can be implemented as a thin film transistor (TFT). The transistors can be implemented as an oxide thin film transistor (Oxide TFT) including an oxide semiconductor, a low temperature poly silicon TFT (LTPS TFT) including a low temperature poly silicon, and the like.

A transistor is a three-electrode element including a gate, a source, and a drain. The source is an electrode that supplies carriers to the transistor. In the transistor, carriers start to flow from the source. The drain is an electrode through which carriers exit from the transistor. In a transistor, carriers flow from a source to a drain. In the case of an n-channel transistor, since carriers are electrons, a source voltage is a voltage lower than a drain voltage such that electrons can flow from a source to a drain. The n-channel transistor has a direction of a current flowing from the drain to the source. In the case of a p-channel transistor (p-channel metal-oxide semiconductor, since carriers are holes, a source voltage is higher than a drain voltage such that holes can flow from a source to a drain. In the p-channel transistor, since holes flow from the source to the drain, current flows from the source to the drain. It should be noted that a source and a drain of a transistor are not fixed. For example, a source and a drain can be changed according to an applied voltage. Therefore, the disclosure is not limited to a source and a drain of a transistor. In the following description, a source and a drain of a transistor will be referred to as a first electrode and a second electrode.

A gate signal swings between a gate-on voltage and a gate-off voltage. A transistor is turned on in response to a gate-on voltage and is turned off in response to a gate-off voltage. In the case of an n-channel transistor, the gate-on voltage can be a gate high voltage VGH, and the gate-off voltage can be a gate low voltage VGL. In the case of a p-channel transistor, the gate-on voltage can be the gate low voltage VGL, and the gate-off voltage can be the gate high voltage VGH.

Hereinafter, various embodiments of the present disclosure will be described in detail with reference to the accompanying drawings. All the components of each display device/apparatus according to all embodiments of the present disclosure are operatively coupled and configured.

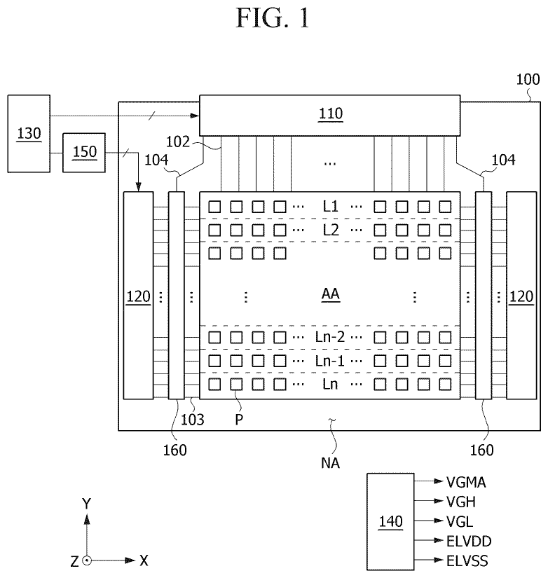

FIG. 1 is a block diagram illustrating a display device according to an embodiment of the present disclosure.

Referring to FIG. 1, the display device according to one embodiment of the present disclosure includes a display panel 100, display panel driving circuits 110 and 120 for writing image data to pixels P of the display panel 100, and a power circuit 140 for generating power necessary for driving the pixels P and the display panel driving circuits 110 and 120.

The display panel 100 can be, but is not limited to, a rectangular shaped panel having a width in the X-axis direction (e.g., first direction), a length in the Y-axis direction (e.g., second direction), and a thickness in the Z-axis direction (e.g., third direction). For example, at least a portion of the display panel 100 can have a curved outer periphery. The display panel 100 can be implemented as a non-transmissive display panel or a transmissive display panel. The transmissive display panel can be applied to a transparent display device in which an image is displayed on a screen and an actual object in the background is visible. The display panel 100 can be implemented as a flexible display panel.

The display panel 100 can include a display area (or active area) AA and a non-display area (or non-active area) NA outside the display area AA. The display area AA of the display panel 100 can include a pixel array for displaying images thereon. The pixel array can include a plurality of data lines 102, a plurality of gate lines 103 intersecting the data lines 102, and the pixels P arranged in a matrix form. The non-display area NA can further include dummy pixels 160, and dummy data lines 104 connecting dummy channels of the data driver 110 to the dummy pixels 160. The gate lines 103 intersect dummy data lines 104. The display panel 100 can further include a plurality of power lines connected in common to the pixel circuits of the pixels P and the pixel circuits of the dummy pixels 160. Each of the power lines contains a constant voltage node connected to the pixel circuit.

The pixels P can include two or more sub-pixels for color implementation. For example, each of the pixels P can be divided into a red sub-pixel, a green sub-pixel, and a blue sub-pixel. Each of the pixels P can further include a white sub-pixel. Each sub-pixel includes a pixel circuit for driving a light-emitting element.

Each of the sub-pixels of the pixels P can be connected to the data line 102, the gate line 103, and the power line. The dummy pixels 160 can be connected to the dummy data lines 104, the gate lines 103, and the power lines.

The pixel array of the display area AA can include a plurality of pixel lines L1 to Ln. Each of the pixel lines L1 to Ln can include one line of the pixels P arranged along the X-axis direction in the pixel array of the display panel 100. The pixels P arranged in one pixel line can share the gate lines 103. The pixels arranged along the column direction (Y-axis direction) along a data line direction can share the data lines 102. One horizontal period is a time obtained by dividing one frame period by the total number of the pixel lines L1 to Ln.

The dummy pixels 160 can be disposed between the pixels P of the display area AA and the gate driver 120 in the non-display area NA of the display panel 100. The dummy pixels 160 can include a plurality of dummy pixel circuits arranged in the non-display area NA to correspond to the pixel lines L1 to Ln. For example, a first dummy pixel circuit can be disposed in the non-display area NA on an extension line of the first pixel line L1. A pixel circuit of a second dummy pixel can be disposed in the non-display area NA on the extension line of the second pixel line L2. The dummy data line 104 is connected to a dummy channel of the data driver 110 to apply the data voltage output from the dummy channel to the dummy pixel circuit.

The driving circuits 110, 120 of the display panel 100 write pixel data of the input image to the pixels under the control of the timing controller 130.

The timing controller 130 can receive the pixel data of the input image, and a timing signal synchronized with the pixel data from the host system 200. The timing signal can include a vertical synchronization signal Vsync, a horizontal synchronization signal Hsync, a main clock CLK, and a data enable signal DE. One cycle of the vertical synchronization signal Vsync can be a period of one frame. One cycle of the horizontal synchronization signal Hsync and the data enable signal DE can be one horizontal period 1H. The pulse of the data enable signal DE can be synchronized with one line of data to be written to the pixels P on one pixel line. Since a frame period and a horizontal period can be known by counting the data enable signal DE, the vertical synchronization signal Vsync and the horizontal synchronization signal Hsync can be omitted. The timing controller 130 can transmit the pixel data of the input image to the data driver 110 and control the operation timing of the data driver 110 and the gate driver 120. A gate timing control signal generated from the timing controller 130 can be input to the gate driver 120 through a level shifter 150.

The level shifter 150 can receive the gate timing control signal to output a start pulse and a shift clock. An input signal to the level shifter 150 can be a signal of a digital signal voltage level, and an output signal from the level shifter 150 can be an analog voltage signal that swings between a gate high voltage VGH and a gate low voltage VGL. The level shifter 150 can convert a low level voltage of the gate timing signal output from the timing controller 130 to the gate low voltage (VGL) and a high level voltage to the gate high voltage (VGH).

The data driver 110 can receive pixel data of the input image received as a digital signal from the timing controller 130 and output a data voltage. The data driver 110 can convert the pixel data of the input image into a gamma-compensated voltage using a digital-to-analog converter, hereinafter referred to as “DAC”, and output the data voltage. A gamma reference voltage output from the power circuit 140 can be divided into the gamma compensated voltage for each grayscale by a voltage divider circuit in the data driver 110 and supplied to the DAC. The DAC can generate the data voltage as the gamma compensated voltage corresponding to the grayscale value of the pixel data. The data voltage from the DAC can be output to the data line 102 and the dummy data line 104 through an output buffer from the respective channels of the data driver 110.

The circuit of the data driver 110 can be integrated into a drive IC (Integrated Circuit). The drive IC can be bonded to the display panel 100 using a chip on glass (COG) process, or it can be implemented as a chip on film (COF) and bonded to the display panel 100 and electrically connected to the data lines 102 and 104.

The gate driver 120 can be disposed on the display panel 100. The gate driver 120 can be disposed in the non-display area NA outside the display area AA in the display panel 100, or it can be partially disposed in the display area AA. The gate driver 120 can supply a gate signal to the gate lines 103 in a single feeding method. In the single feeding method, the gate signal can be applied at one ends of the gate lines 103. In a double feeding method, the gate signal can be applied simultaneously at opposite ends of the gate lines 103. The gate signal output from the gate driver 120 can be applied to the pixels P of the display area AA and the dummy pixels 160 of the non-display area NA.

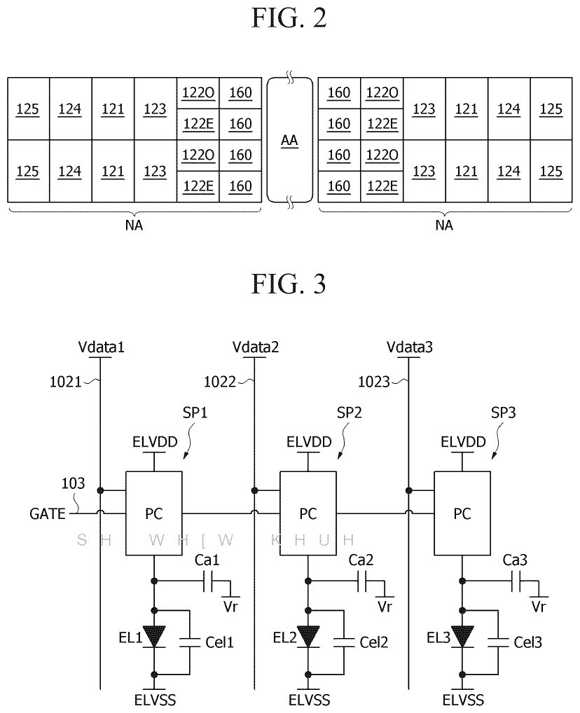

When a plurality of gate signals are applied to the pixel circuits of the pixels P and the dummy pixels 160, as illustrated in FIG. 2, the gate driver 120 can include a plurality of gate drivers that output different gate signals. Each of the gate drivers can include circuits such as a shift register and an edge trigger and can shift the pulse of the gate signal.

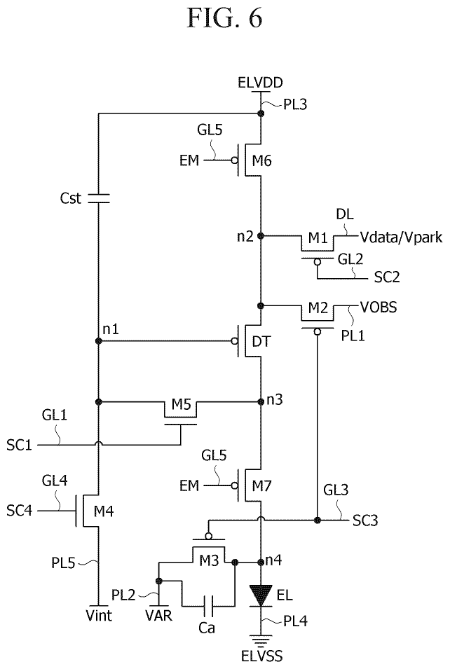

The power supply circuit 140 can include a charge pump, a regulator, a buck converter, a boost converter, and the like, but the embodiment of the present disclosure is not limited thereto. The power supply circuit 140 can receive a direct-current input voltage from the host system and can generate electric power necessary for driving the driving circuits 110 and 120 and the pixels P of the display panel 100. The power supply circuit 140 can output constant voltages (or DC voltages) such as a gamma reference voltage, a gate high voltage VGH, and a gate low voltage VGL. Further, the power supply circuit 140 can outputs constant voltages that are provided to the pixels P. The gamma reference voltage can be supplied to the data driver 110. The gate high voltage VGH and the gate low voltage VGL can be supplied to the level shifter 150 and the gate driver 120. The constant voltages that are input to the pixel circuit, for example, a pixel driving voltage ELVDD, a pixel ground voltage ELVSS, and the like can be applied to the pixels P and the dummy pixels 160 via the power lines in common to the pixels P. The pixel ground voltage ELVSS can be a cathode voltage. The power supply circuit 140 outputs constant voltages such as an initialization voltage Vinit, an anode reset voltage VAR, and an on bias voltage VOBS illustrated in FIG. 6. The power supply circuit 140 can be implemented by a power IC such as a power management integrated circuit (PMIC) or an electronics integrated circuit (ELIC), but the embodiment of the present disclosure is not limited thereto.

The driving circuits 110 and 120 of the display panel 100 can be driven at a variable refresh rate (VRR) under the control of the timing controller 130. For example, the timing controller 130 can reduce power consumption of the display device by analyzing the input image and lowering the refresh rate when the input image does not change by a preset amount of time. In this case, the driving circuit of the display panel 100 can lower the refresh rate of the pixels P when a still image is input for a certain period of time or more under the control of the timing controller 130 to control a data writing period of the pixels P to be longer, thereby reducing the power consumption of the display device. The driving circuit of the display panel 100 can reduce the refresh rate when the display device is operated in standby mode or in response to a user command. Further, the refresh rate can be lowered in an always on display (AOD) screen. The AOD screen can be a small area of pixels in the display area AA in which preset information, for example, brief information such as remaining battery power, time, and the like are displayed in the standby mode.

When the refresh rate is lowered, the frame frequency is lowered. In this case, pixel data can be written to the pixels in a refresh frame period, and during an expanded vertical blank period, light can be continuously emitted while maintaining data voltage charged in a previous refresh frame period without writing new pixel data. The expanded vertical blank period can be interpreted as a hold frame period or a skip frame period. Hereinafter, when the refresh rate is lowered, the expanded vertical blank period will be described as the hold frame period.

The gate signals such as a first scan signal SC1, second scan signal SC2, a third scan signal SC3, a fourth scan signal SC4, and a light emission signal (hereinafter, referred to as an “EM signal”) can be applied to the pixel circuit illustrated in FIG. 6. In this case, as illustrated in FIG. 2, the gate driver 120 can include a first gate driver 121 that outputs the first scan signal SC1, second gate drivers 122O and 122E that output the second scan signal SC2, a third gate driver 123 that outputs the third scan signal SC3, a fourth gate driver 124 that outputs the fourth scan signal SC4, and a fifth gate driver 125 that outputs the EM signal EM. Each of the first to fifth gate drivers output the pulse and sequentially shifts the pulse during the refresh frame period. In the hold frame period during which a low refresh rate is set, the first, second, and fourth gate drivers do not need to output the pulse. Accordingly, when the refresh rate is lowered, the power consumption of the gate driver 120 can be sharply reduced.

FIG. 2 is a plan view illustrating a planar arrangement of gate drivers according to the embodiment of the present disclosure. The gate driver 120 is not limited to that illustrated in FIG. 2 and other variations are possible.

Referring to FIG. 2, a plurality of gate signals can be applied to the pixels. For example, the gate driver 120 can apply the first scan signal SC1, the second scan signal SC2, the third scan signal SC3, the fourth scan signal SC4, and the EM signal EM. In this case, the gate driver 120 can include the first gate driver 121 that outputs the first scan signal SC1, the second gate drivers 122O and 122E that output the second scan signal SC2, the third gate driver 123 that outputs the third scan signal SC3, the fourth gate driver 124 that outputs the fourth scan signal SC4, and the fifth gate driver 125 that outputs the EM signal EM. The dummy pixels 160 can be provided between the gate driver 120 and the pixels of the display area AA.

The second gate drivers 122O and 122E can be implemented by a shift register circuit and other gate drivers 121, 123, 124, and 125 can be implemented by an edge trigger, but the embodiment of the present disclosure is not limited thereto. The edge trigger has an advantage in outputting a gate signal in common to two or more pixel lines due to a driving method. The second gate drivers 122O and 122E can include an odd-numbered scan driver 122O that supplies the second scan signal SC2 to sub-pixels of odd-numbered pixel lines, and an even-numbered scan driver 122E that supplies the second scan signal SC2 to sub-pixels of even-numbered pixel lines. The first, third, fourth, and fifth gate drivers 121, 123, 124, 125 can be implemented by an edge trigger that is connected in common to sub-pixels of two pixel lines, but the embodiment of the present disclosure is not limited thereto.

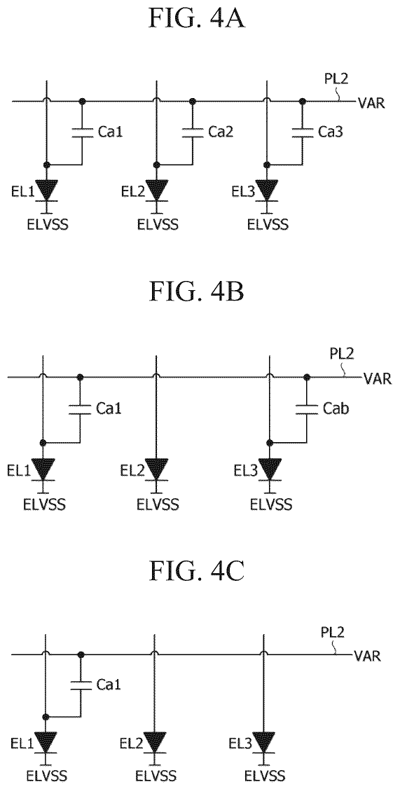

The light-emitting elements can be different in turn-on start time by color. For example, since the light-emitting elements of the red sub-pixels have a capacitor having a capacitance smaller than a capacitance of a capacitor in the green and blue light-emitting elements, the light-emitting elements of the red sub-pixels can be turned on earlier than the green and blue light-emitting element. For improvement of low-grayscale stain characteristics, while it is advantageous that, when a light emission period starts, an anode voltage of a light-emitting element is set to a voltage close to a threshold voltage at which the light-emitting element can be turned on, a light-emitting element with a capacitor having a relatively smaller capacitance, for example, a red light-emitting element can be turned on earlier. To improve such a problem, an anode reset voltage of a light-emitting element by color can be separated. In this case, however, power wires to which the anode reset voltage is applied should be added, and a control signal for controlling the anode reset voltage can be added. In the present disclosure, as illustrated in FIG. 3, by compensating for ununiform charging characteristics of different light-emitting elements by color using compensation capacitors additionally connected to light-emitting elements EL1, EL2, and EL3, it is possible to improve image quality including improvement of low-grayscale stains.

FIG. 3 is a circuit diagram illustrating sub-pixels according to the embodiment of the present disclosure.

Referring to FIG. 3, each of the pixels P includes a first sub-pixel including a first pixel circuit PC that drives a first light-emitting element EL1, a second sub-pixel including a second pixel circuit PC that drives a second light-emitting element EL2, and a third sub-pixel including a third pixel circuit PC that drives a third light-emitting element EL3. The first light-emitting element (EL1), the second light-emitting element (EL2), and the third light-emitting element (EL3) can emit light of different wavelengths so as to emit light of different colors.

The sub-pixels SP1, SP2, and SP3 include compensation capacitors Ca1, Ca2, and Ca3 connected to anode electrodes of the light-emitting elements EL1, EL2, and EL3, respectively.

The sub-pixels SP1, SP2, and SP3 include the light-emitting elements EL1, EL2, and EL3 that are driven by the pixel circuits PC, respectively. The pixel circuits PC charge data voltages Vdata1 to Vdata3 of pixel data via data lines 1021 to 1023 and generate currents for driving the light-emitting elements EL1, EL2, and EL3 according to gate-source voltages of driving transistors, respectively. Each pixel circuit PC can include an internal compensation circuit that samples a threshold voltage of the driving transistor and compensates for the threshold voltage. The constant voltages such as at least the pixel driving voltage ELVDD and the pixel ground voltage ELVSS can be applied to the pixel circuit PC.

Capacitors Cel1, Cel2, and Cel3 can have different capacitances depending on the colors of the light-emitting elements EL1, EL2, and EL3. As an example, a capacitor of a red OLED can have a capacitance smaller than those of capacitors of green and blue OLEDs. In this case, a light emission start time of the red OLED can be earlier than those of the green and blue OLEDs.

The first sub-pixel SP1 can be a red sub-pixel including the first light-emitting element EL1. The second sub-pixel SP2 can be a green sub-pixel including the second light-emitting element EL2, and the third sub-pixel SP3 can be a blue sub-pixel including the third light-emitting element EL3. The first light-emitting element EL1 can be a red light-emitting element that emits red light. The second light-emitting element EL2 can be a green light-emitting element that emits green light, and the third light-emitting element EL3 can be a blue light-emitting element that emits blue light. A wavelength of a light emitted by the first light-emitting element EL1 is larger than a wavelength of a light emitted by the second light-emitting element EL2, and the wavelength of the light emitted by the second light-emitting element EL2 is larger than a wavelength of a light emitted by the third light-emitting element EL3. The light-emitting elements EL1, EL2, and EL3 include the capacitors Cel1, Cel2, and Cel3, respectively. To compensate for a difference in capacitance among the capacitors of the light-emitting elements EL1, EL2, and EL3, the compensation capacitor Ca1 can be connected to the anode electrode of at least the first light-emitting element EL1.

The compensation capacitors Ca1, Ca2, and Ca3 can be connected to the light-emitting elements EL1, EL2, and EL3, respectively. For example, the first compensation capacitor Ca1 can be connected between the anode electrode of the first light-emitting element EL1 and a power line (or a constant voltage node) to which a reference voltage Vr is applied. The reference voltage Vr can be a voltage selected from the constant voltages that are applied to the pixel circuit, for example, ELVDD, ELVSS, Vinit, VOBS, VAR, and the like illustrated in FIG. 6.

The capacitance of the first compensation capacitor Ca1 can be greater than the capacitance of each of the second and third compensation capacitors Ca2 and Ca3 connected to the anode electrodes of the second and third light-emitting elements EL2 and EL3. The capacitance of the third compensation capacitor Ca3 can be smaller than that of the first compensation capacitor Ca1 and equal to or greater than that of the second compensation capacitor Ca2.

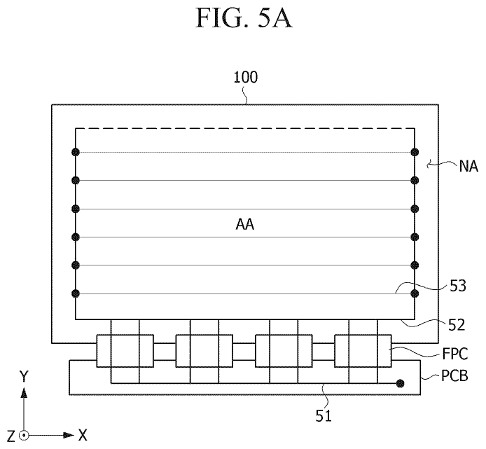

FIGS. 4A to 4C are diagrams illustrating various examples where a compensation capacitor is connected to a power line to which an anode reset voltage is applied according to aspects of the present disclosure.

Referring to an example shown in FIG. 4A, the first compensation capacitor Ca1 can be connected between the anode electrode of the first light-emitting element EL1 and a power line PL2 to which the anode reset voltage VAR is applied. The second compensation capacitor Ca2 can be connected between the anode electrode of the second light-emitting element EL2 and the power line PL2. The third compensation capacitor Ca3 can be connected between the anode electrode of the third light-emitting element EL3 and the power line PL2. The capacitance of the first compensation capacitor Ca1 can be greater than the capacitance of each of the second and third compensation capacitors Ca2 and Ca3. The capacitance of the first compensation capacitor Ca1 can be greater than the capacitance of the second compensation capacitor Ca2.

Referring to another example shown in FIG. 4B, a first compensation capacitor Ca1 can be connected between the anode electrode of the first light-emitting element EL1 and the power line PL2. A second compensation capacitor Cab can be connected between the anode electrode of the third light-emitting element EL3 and the power line PL2. The capacitance of the first compensation capacitor Ca1 can be greater than the capacitance of the second compensation capacitor Cab. In this case, while the compensation capacitors Ca1 and Cab are formed in the first and third sub-pixels SP1 and SP3, respectively, the second sub-pixel SP2 can be implemented without a compensation capacitor.

Referring to still another example of FIG. 4C, a first compensation capacitor Ca1 can be connected between the anode electrode of the first light-emitting element EL1 and the power line PL2. The second and third compensation capacitors Ca2 and Ca3 can be omitted. In this case, while the compensation capacitor Ca1 is formed in the first sub-pixel SP1, the second and third sub-pixels SP2 and SP3 can be implemented without a compensation capacitor.

As illustrated in FIGS. 3 to 4C, the compensation capacitors Ca1, Ca2, and Ca3 can be connected in common to the single power line PL2 that crosses the sub-pixels SP1, SP2, and SP3.

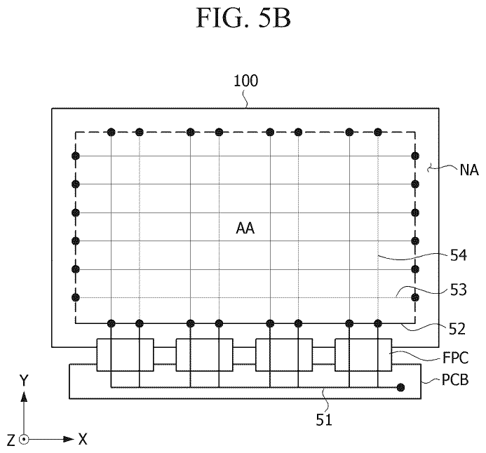

FIGS. 5A and 5B are diagrams illustrating patterns of data lines provided in the display panels according to aspects of the present disclosure. Power lines 51 to 54 illustrated in FIGS. 5A and 5B can be power lines to which the anode reset voltage VAR is applied. A wire corresponding to a dotted-line portion in an outside power line 52 of the display panel 100 illustrated in FIGS. 5A and 5B represents a portion that can be omitted.

Referring to FIG. 5A, the display panel 100 can be electrically connected to a printed circuit board (PCB) via a flexible film FPC. The flexible film can be a chip on film (COF) or a flexible printed circuit (FPC).

The PCB includes the power line 51 to which the anode reset voltage VAR is applied. The flexible film FPC includes the power line 52 connected to the power line 51 of the PCB. The display panel 100 includes the power line 52 provided in the non-display area NA, and the power lines 53 in the display area AA connected to the power line 52. The power lines 53 provided in the display area AA can be metal wires provided in parallel along the X-axis direction. The power lines 52 and 53 formed on the display panel 100 can be electrically connected via contact holes passing through an insulating layer for insulating metal layers, but the embodiment of the present disclosure is not limited thereto.

In the display area AA of the display panel 100, as illustrated in FIG. 5B, the power lines 53 and 54 that intersect each other in a matrix can be provided. The power lines 53 in the X-axis direction and the power lines 54 in the Y-axis direction can be separated with an insulating layer interpose therebetween and can be electrically connected via contact holes passing through the insulating layer, but the embodiment of the present disclosure is not limited thereto.

FIG. 6 is a circuit diagram illustrating a pixel circuit according to the embodiment of the present disclosure.

Referring to FIG. 6, the pixel circuit includes a light-emitting element EL, a driving element DT that drives the light-emitting element EL, a plurality of switch elements M1 to M7, and capacitors Cst and Ca. Each of the fourth and fifth switch elements M4 and M5 can be implemented by an n-channel Oxide TFT having a low off-current. Each of the driving element DT and the first, second, third, sixth, and seventh switch elements M1, M2, M3, M6, and M7 can be implemented by a p-channel LTPS TFT having a high on-current characteristic. The n-channel Oxide TFT can be turned on in response to a gate high voltage VGH and can be turned off in response to a gate low voltage VGL, but the embodiment of the present disclosure is not limited thereto. The p-channel LTPS TFT can be turned on in response to the gate low voltage VGL and can be turned off in response to the gate high voltage VGH, but the embodiment of the present disclosure is not limited thereto.

The light-emitting element EL can be implemented by an OLED or an inorganic LED such as a micro LED. The OLED includes an anode electrode, a cathode electrode, and an organic compound layer interposed between the electrodes. The anode electrode of the light-emitting element EL can be connected to a fourth node n4, and a cathode electrode of the light-emitting element EL can be connected to a fourth power line PL4 to which a pixel ground voltage is applied. The organic compound layer can include a hole injection layer (HIL), a hole transport layer (HTL), a light emission layer (EML), an electron transport layer (ETL), and an electron injection layer (EIL), but the embodiment of the present disclosure is not limited thereto. When a voltage is applied to the anode electrode and the cathode electrode of the light-emitting element EL, holes passing through the hole transport layer (HTL) and electrons passing through the electron transport layer (ETL) are moved to the light emission layer (EML) to form excitons. In this case, visible light is emitted from the light emission layer (EML). The OLED can be implemented by an OLED having a tandem structure in which a plurality of light emission layers are stacked. With the OLED having the tandem structure, the luminance and lifetime of the pixels can be improved. The light-emitting element EL includes capacitors Cel1, Cel2, and Cel3 as in FIG. 3.

The pixel circuit can be connected to a data line DL and gate lines GL1 to GL5. A data voltage Vdata of pixel data and a park voltage Vpark set regardless of the pixel data can be applied to the data line DL. The park voltage Vpark can be set to a value empirically determined to compensate for change in luminance of pixels between the refresh frame period and the hold frame period at a low refresh rate. At the low refresh rate, under the control of the timing controller 130, the data driver 110 can output the data voltage Vdata in the refresh frame period and can output the park voltage Vpark in the hold frame period.

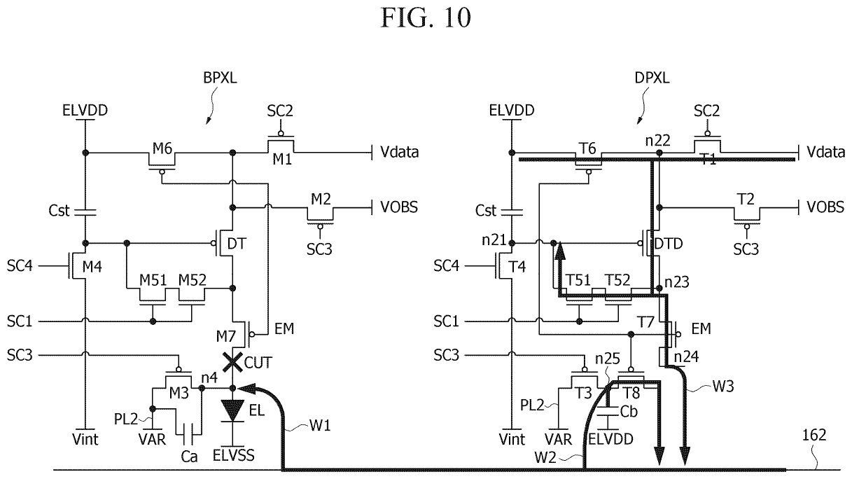

The gate signals SC1 to SC4 and EM include pulses that swing between the gate high voltage VGH and the gate low voltage VGL as illustrated in FIGS. 10 and 13. The gate driver 120 can output the gate signals SC1 to SC4 and EM using the gate drivers 121 to 125 as in FIG. 2.

The pixel circuit can be connected to a first power line PL1 to which the on bias voltage VOBS is applied, a second power line PL2 to which the anode reset voltage VAR is applied, a third power line PL3 to which the pixel driving voltage ELVDD is applied, a fourth power line PL4 to which the pixel ground voltage ELVSS is applied, and a fifth power line PL5 to which the initialization voltage Vinit is applied. On the display panel 100, the power lines PL1 to PL5 can be connected in common to all pixels 101.

The pixel driving voltage ELVDD and the pixel ground voltage ELVSS are set to voltages at which the driving element DT can operate in a saturation region. The pixel driving voltage ELVDD can be set to a voltage of 2 [V] to 3 [V] and the pixel ground voltage ELVSS can be set to a voltage of −8 [V] to −10 [V], but the embodiment of the present disclosure is not limited thereto. The gate high voltage VGH can be set to a voltage higher than the pixel driving voltage ELVDD and the gate low voltage VGL can be set to a voltage lower than the pixel ground voltage ELVSS, but the embodiment of the present disclosure is not limited thereto.

The data voltage Vdata can have a dynamic range of 2 [V] to 6 [V]. Within the dynamic range, a voltage level of the data voltage Vdata is selected according to a grayscale value of the pixel data. The initialization voltage Vinit can be set to a voltage lower than a lower limit voltage of the data voltage Vdata and higher than the pixel ground voltage ELVSS. For example, when the lower limit voltage of the data voltage Vdata is 2 [V], and the pixel ground voltage ELVSS is −9 [V], the initialization voltage Vinit can be set to a voltage of −5 [V] to −7 [V].

The park voltage Vpark can be set within a voltage range smaller than the dynamic range of the data voltage Vdata within the dynamic range of the data voltage Vdata. For example, when the dynamic range of the data voltage Vdata is 2 [V] to 6 [V], the park voltage Vpark can be set to a specific voltage of 4 [V] to 6 [V]. The on bias voltage VOBS can be set within a voltage range partially overlapping the dynamic range of the data voltage Vdata. For example, when the dynamic range of the data voltage Vdata is 2 [V] to 6 [V], the on bias voltage VOBS can be set to a voltage of 4 [V] to 8 [V]. The on bias voltage VOBS sets the gate-source voltage of the driving element DT to the on bias voltage, thereby improving the hysteresis of the driving element DT. The anode reset voltage VAR periodically resets the anode electrode of the light-emitting element at the low refresh rate, thereby improving a phenomenon in which a flicker due to a difference in anode voltage of the light-emitting element between the refresh frame period and the hold frame period is visible. The anode reset voltage VAR can be set to a voltage higher than the pixel ground voltage ELVSS by about 0.5 V to 1.0 V, but the embodiment of the present disclosure is not limited thereto.

The driving element DT drives the light-emitting element EL with a current generated according to the gate-source voltage thereof during the light emission period. The driving element DT includes a gate electrode connected to a first node n1, a first electrode connected to a second node n2, and a second electrode connected to a third node n3.

A first switch element M1 is connected between the data line DL and the second node n2. The first switch element M1 is turned on in response to the gate low voltage VGL of the second scan signal SC2. When the first switch element M1 is turned on, the data line DL can be electrically connected to the second node n2. The first switch element M1 includes a gate electrode connected to a second gate line GL2 to which the second scan signal SC2 is applied, a first electrode connected to the data line DL, and a second electrode connected to the second node n2.

A second switch element M2 is connected between the second node n2 and the first power line PL1 to which the on bias voltage VOBS is applied. The second switch element M2 is turned on in response to the gate low voltage VGL of the third scan signal SC3. When the second switch element M2 is turned on, the on bias voltage VOBS is applied to the second node n2. The second switch element M2 includes a gate electrode connected to a third gate line GL3 to which the third scan signal SC3 is applied, a first electrode connected to the second node n2, and a second electrode connected to the first power line PL1.

A third switch element M3 is connected between the fourth node n4 and the second power line PL2 to which the anode reset voltage VAR is applied. The third switch element M3 is turned on in response to the gate low voltage VGL of the third scan signal SC3. When the third switch element M3 is turned on, the anode reset voltage VAR can be applied to the fourth node n4. The third switch element M3 includes includes a gate electrode connected to the third gate line GL3, a first electrode connected to the fourth node n4, and a second electrode connected to the second power line PL2.

A fourth switch element M4 is connected between the first node n1 and the fifth power line PL5 to which the initialization voltage Vinit is applied. The fourth switch element M4 is turned on in response to the gate high voltage VGH of the fourth scan signal SC4. When the fourth switch element M4 is turned on, the initialization voltage Vinit is applied to a storage capacitor Cst connected to the first node n1 and the gate electrode of the driving element DT. The fourth switch element M4 includes a gate electrode connected to a fourth gate line GL4 to which the fourth scan signal SC4 is applied, a first electrode connected to the first node n1, and a second electrode connected to the fifth power line PL5.

A fifth switch element M5 is connected between the first node n1 and the third node n3. The fifth switch element M5 is turned on in response to the gate high voltage VGH of the first scan signal SC1. When the fifth switch element M5 is turned on, the first node n1 is connected to the third node n3. When the fifth switch element M5 is turned on, the gate electrode and the second electrode of the driving element DT can be connected, and the driving element DT can operate as a diode. The fifth switch element M5 includes a gate electrode connected to a first gate line GL1 to which the first scan signal SC1 is applied, a first electrode connected to the first node n1, and a second electrode connected to the third node n3.

A sixth switch element M6 is connected between the third power line PL3 to which the pixel driving voltage ELVDD is applied and the second node n2. The sixth switch element M6 is turned on in response to the gate low voltage VGL of the EM signal EM. When the sixth switch element M6 is turned on, the pixel driving voltage ELVDD can be applied to the second node n2. The sixth switch element M6 includes a gate electrode connected to a fifth gate line GL5 to which the EM signal EM is applied, a first electrode connected to the third power line PL3, and a second electrode connected to the second node n2.

A seventh switch element M7 is connected between the third node n3 and the fourth node n4. The seventh switch element M7 is turned on in response to the gate low voltage VGL of the EM signal EM and electrically connects the third node n3 to the fourth node n4. The seventh switch element M7 includes a gate electrode connected to the fifth gate line GL5, a first electrode connected to the third node n3, and a second electrode connected to the fourth node n4.

The storage capacitor Cst is connected between a node on the third power line PL3 to which the pixel driving voltage ELVDD is applied and the first node n1 and maintains the gate-source voltage of the driving element DT. A compensation capacitor Ca can be connected between the fourth node n4 and the second power line PL2, but the embodiment of the present disclosure is not limited thereto. For example, the compensation capacitor Cst can be connected to one of the first power line PL1, the second power line PL2, the third power line PL3, the fourth power line PL4, and the fifth power line PL5 and the fourth node n4.

As illustrated in FIGS. 3 to 4C, the compensation capacitor Ca can be formed in one or more of the first, second, and third sub-pixels SP1, SP2, and SP3. The compensation capacitor Ca can be connected between the fourth node n4 and the power line PL2. The capacitance of the compensation capacitor Ca can be set to a value equal or similar to the capacitance of the storage capacitor Cst. The capacitance of each of the compensation capacitor Ca and the storage capacitor Cst is smaller than the capacitance of each of the capacitors Cel1, Cel2, and Cel3 of the light-emitting elements EL illustrated in FIG. 3. The capacitance of each of the capacitors Cel1, Cel2, and Cel3 of the light-emitting elements EL is 100 (fF) to 400 (fF), and the capacitance of the capacitor of the light-emitting element provided in the red sub-pixel can be the smallest in this capacitance range. The capacitance of each of the compensation capacitor Ca and the storage capacitor Cst can be 50 (fF) to 90 (fF), but the embodiment of the present disclosure is not limited thereto.

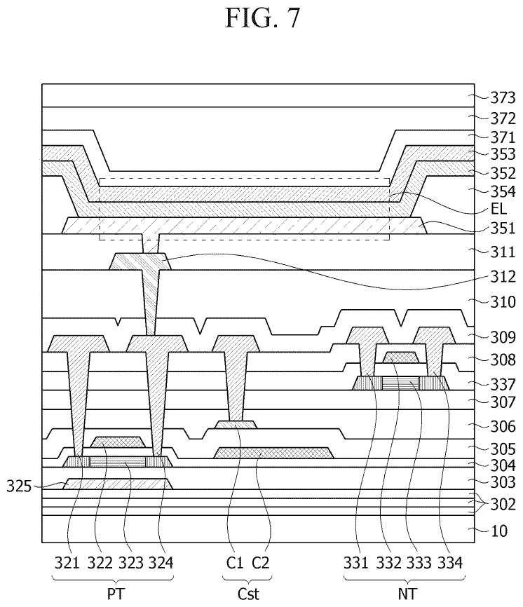

FIG. 7 is a cross-sectional view illustrating a cross-sectional structure of a pixel according to the embodiment of the present disclosure. In FIG. 7, “PT” represents a p-channel transistor implemented by a p-channel LTPS TFT and “NT” represents an n-channel transistor implemented by an n-channel Oxide TFT. In the pixel circuit illustrated in FIG. 6, each of the driving element DT and the first, second, third, sixth, and seventh switch elements M1, M2, M3, M6, and M7 can be a transistor having the substantially same structure as the p-channel transistor PT. In the pixel circuit illustrated in FIG. 6, each of the fourth and fifth switch elements M4 and M5 can be a transistor having the substantially same structure as the n-channel transistor NT.

Referring to FIG. 7, a substrate 10 of the display panel 100 can be a structure having a multi-layer structure in which an organic film and an inorganic film are alternately. For example, the substrate 10 can have a structure in which an organic film such as polyimide and an inorganic film such as silicon oxide (SiOx) are stacked, but the embodiment of the present disclosure is not limited thereto.

A first metal layer 325 can be provided above the substrate 10 of the display panel 100. A buffer layer 302 with one or more insulating layers stacked can be provided between the substrate 10 and the first metal layer 324. The buffer layer 302 can block moisture and the like that can be penetrated from the outside. The buffer layer 302 can have a multi-layer structure in which silicon oxide (SiOx), silicon nitride (SiNx), and the like are stacked. The first metal layer 325 can be a metal layer having a single layer or a multi-layer structure made of one or an alloy of molybdenum (Mo), aluminum (Al), chromium (Cr), nickel (Ni), neodymium (Nd), and copper (Cu).

An insulating layer 303 can cover the first metal layer 325 and the buffer layer 302. The insulating layer 303 can be composed of a silicon oxide film (SiOx), a silicon nitride film (SiNx), or a dual-layer of a silicon oxide film (SiOx) and a silicon nitride film (SiNx). A semiconductor layer 323 of a p-channel transistor PT can be provided above the insulating layer 303. The semiconductor layer 323 can be made of polysilicon. The insulating layer 304 can cover the semiconductor layer 323 and the insulating layer 303. The insulating layer 304 can be formed of the same insulating material as the insulating layer 303.

A second metal layer can be provided above the insulating layer 304. The second metal layer can include a gate electrode 322 of the p-channel transistor PT, a gate line connected to the gate electrode 322, a lower electrode C2 of the storage capacitor Cst, and the like. The second metal layer can be a metal layer having a single layer or a multi-layer structure made of one or an alloy of molybdenum (Mo), aluminum (Al), chromium (Cr), gold (Au), titanium (Ti), nickel (Ni), neodymium (Nd), tungsten (W), and copper (Cu).

An insulating layer 305 can cover the second metal layer and the insulating layer 304. The insulating layer 305 can be formed of the same insulating material as the insulating layer 303. A third metal layer can be provided above the insulating layer 305. The third metal layer can include an upper electrode C1 of the storage capacitor Cst. The third metal layer can be formed of the same metal as the second metal layer, but the embodiment of the present disclosure is not limited thereto.

Insulating layers 306 and 307 can be stacked above the third metal layer and the insulating layer 305. The insulating layers 306 and 307 can be formed of the same insulating material as the insulating layer 303, but the embodiment of the present disclosure is not limited thereto. A semiconductor layer 333 of an n-channel transistor NT can be provided above the insulating layer 307. The semiconductor layer 333 can be made of an oxide semiconductor.

An insulating layer 337 can cover the insulating layer 307 and the semiconductor layer 333. The insulating layer 337 can be formed of the same insulating material as the insulating layer 303, but the embodiment of the present disclosure is not limited thereto. A fourth metal layer can be provided above the insulating layer 337. The fourth metal layer can include a gate electrode 332 of the n-channel transistor NT, a gate line connected to the gate electrode 332, and the like. The fourth metal layer can be formed of the same metal as the second metal layer, but the embodiment of the present disclosure is not limited thereto.

An insulating layer 308 can cover the fourth metal layer and the insulating layer 337. The insulating layer 308 can be formed of the same insulating material as the insulating layer 303, but the embodiment of the present disclosure is not limited thereto. A fifth metal layer can be provided above the insulating layer 308. The fifth metal layer can include first and second electrodes 321, 324, 331, and 334 of transistors PT and NT, a data line, and the like. The first and second electrodes 321, 324, 331, and 334 of the transistors PT and NT can be in contact with the corresponding semiconductor layers 323 and 333 via contact holes passing through the underlying insulating layers. The fifth metal layer can be a metal layer having a single layer or a multi-layer structure made of one or an alloy of molybdenum (Mo), aluminum (Al), chromium (Cr), gold (Au), titanium (Ti), nickel (Ni), neodymium (Nd), and copper (Cu), but the embodiment of the present disclosure is not limited thereto.

A protection layer 309 can cover the underlying insulating layer 308 and the fifth metal layer. The protection layer 309 can be formed of the same insulating material as the insulating layer 303, but the embodiment of the present disclosure is not limited thereto. A first planarization layer 310 can cover the protection layer 309, and a sixth metal layer can be provided above the first planarization layer 310. The sixth metal layer can include a connection electrode 312 that is connected to a first electrode or a second electrode of the p-channel transistor PT via a contact hole passing through the first planarization layer 310. The first planarization layer 310 can planarize the upper portions of the transistors PT and NT and can protect the transistors PT and NT.

A second planarization layer 311 can cover the sixth metal layer and the first planarization layer 310. A light-emitting element EL can be provided above the second planarization layer 311. The light-emitting element EL can include an anode electrode 351, an organic compound layer 352, a cathode electrode 353, and a bank layer 354.

The planarization layers 310 and 311 can be made of an organic insulating material. The planarization layers 310 and 311 can be formed of an organic material including acrylic resin, epoxy resin, phenolic resin, polyamide resin, or polyimide resin. The connection electrode 312 of the sixth metal layer can be provided between the first planarization layer 310 and the second planarization layer 311. The connection electrode 312 can electrically connect the p-channel transistor PT and the light-emitting element EL. The connection electrode 312 can be formed of the same metal as the fifth metal layer.

The bank layer 354 that exposes the anode electrode 351 can be provided above the second planarization layer 311. The size and shape of the light emission area in each sub-pixel can be different due to the bank layer 354. The bank layer 354 can be formed of an organic insulating material having photosensitivity. The bank layer 354 can be implemented by a black bank including a black pigment, black resin, graphite, black ink, or the like to absorb visible light. The bank layer 354 can be provided to cover an edge portion of the anode electrode 351.

Spacers can be provided above the bank layer 354. The spacers can buffer an empty space between the substrate 10 on which the light-emitting element EL is formed and an upper substrate to absorb shock from the outside. The spacers can be formed of the same material as the bank layer 354, and can be formed simultaneously with the bank layer 354.

The organic compound layer 352 of the light-emitting element EL can cover the anode electrode 351 and the bank layer 354. The cathode electrode 353 of the light-emitting element EL can be provided above the organic compound layer 352.

A capping layer can be provided above the cathode electrode 353. The capping layer can reduce damage to the cathode electrode 353 of the light-emitting element EL and the organic compound layer 352 below the cathode electrode 353 from an external light source. The capping layer can be formed of an organic or inorganic film. The capping layer can be provided using a material such as LiF as an inorganic film and can further include a layer of an organic film.

The anode electrode 351 can include a stacked structure (Ti/Al/Ti) of aluminum (Al) and titanium (Ti), a stacked structure (ITO/Al/ITO) of aluminum (Al) and ITO, indium tin oxide (ITO), indium zinc oxide (IZO), or a metal material having high reflectance. The cathode electrode 353 can include a transparent conductive material such as indium tin oxide (ITO) or indium zinc oxide (IZO) or a metal that transmits visible light.

An encapsulation layer can be provided above the cathode electrode 353. The encapsulation layer can protect the light-emitting element EL from oxygen and/or moisture from the outside. The encapsulation layer can include two or more stacked insulating layers 371, 372, and 373 including an inorganic film and an organic film. A touch sensor layer can be provided above the encapsulation layer.

The power lines 52, 53, and 54 on the display panel 100 illustrated in FIGS. 5A and 5B can be formed of metal layers selected from the first to sixth metal layer. For example, the power lines 52 provided in the non-display area NA can be formed of the fifth and sixth metal layers connected via the contact hole passing through the insulating layers 309 and 310 to reduce resistance. The power lines 53 and 54 provided in the display area AA can be formed of metal layers selected from the first to sixth metal layers.

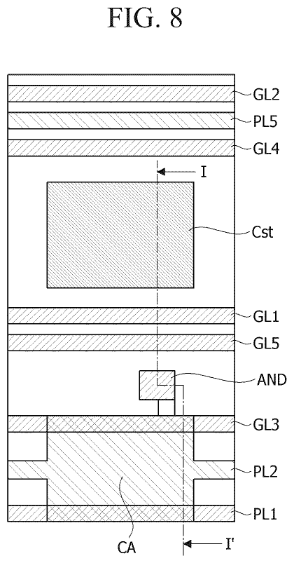

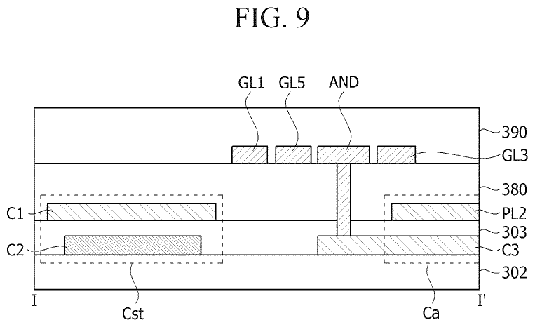

FIGS. 8 and 9 are diagrams illustrating structures of the storage capacitor Cst and the compensation capacitor Ca in the sub-pixel. FIG. 8 is a plan view illustrating a part of a planar arrangement structure of a sub-pixel according to the embodiment of the present disclosure. In FIG. 8, GL1, GL2, GL3, GL4, and GL5 represent gate lines, and PL1, PL2, and PL5 represent power lines. “AND” represents a connection electrode that is connected to the anode electrode of the light-emitting element EL. FIG. 9 is a cross-sectional view of the display panel taken along line I-I′ in FIG. 8.

Referring to FIGS. 6, 7, 8, and 9, the compensation capacitor Ca has a structure similar to the storage capacitor Cst. The capacitance of the compensation capacitor Ca can be the substantially same as or similar to the capacitance of the storage capacitor Cst, but the embodiment of the present disclosure is not limited thereto.

The second metal layer can include lower electrodes C2 and C3 of the storage capacitor Cst and the compensation capacitor Ca. The third metal layer can include an upper electrode C1 of the storage capacitor Cst and the power line PL2. The compensation capacitor Ca has a structure in which the power line PL2, the insulating layer 305, and the lower electrode C3 are stacked. The anode reset voltage VAR can be applied to the power line PL2, but the embodiment of the present disclosure is not limited thereto. For example, a power line integrated with one electrode of the compensation capacitor Ca can be a power line to which a constant voltage that is applied to the pixel circuit is applied.

An insulating layer 380 can be insulating layers stacked between the third metal layer and the sixth metal layer in FIG. 7. The sixth metal layer can include the connection electrode 312 connected to the first electrode or the second electrode of the p-channel transistor PT, the connection electrode AND connected the lower electrode C3 of the compensation capacitor Ca, and one or more gate lines GL1, GL2, GL3, GL4, and GL5. An insulating layer 390 that covers the sixth metal layer can include the planarization layers 310 and 311 illustrated in FIG. 7.

In a manufacturing process of the display panel 100, a defective sub-pixel can occur. For example, the pixel circuit for driving the light-emitting element EL can be driven normally and the defective sub-pixel can look like bright point defect. The light-emitting element EL of the defective sub-pixel can be electrically connected to a pixel circuit of a dummy pixel in a repair step as in FIG. 10 and can be driven normally by the pixel circuit of the dummy pixel.

FIG. 10 is a circuit diagram illustrating an example where a defective sub-pixel is connected to a dummy pixel and is driven normally. In FIG. 10, BPXL represents a defective sub-pixel, and DPXL represents a dummy pixel. In FIG. 10, CUT represents a cutting position where a circuit node or a wire is disconnected, and W1, W2, and W3 represent welding positions for connecting two wires (or nodes). The defective sub-pixel BPXL is the substantially as that in FIG. 6, except that a fifth switch element is implemented by dual transistors M51 and M52 connected in series to reduce a leakage current.

Referring to FIG. 10, the display panel 100 includes a plurality of repair lines 162 formed along the Y-axis direction (second direction) in each pixel line. The repair lines 162 can be provided in parallel with the gate lines illustrated in FIG. 1. The pixel circuit of the dummy pixel DPXL is connected to the light-emitting element EL of the defective sub-pixel BPXL via the repair line 162 in a pixel line in which the defective sub-pixel BPXL is present.

In the repair step, a node between the seventh switch element M7 and the anode electrode of the light-emitting element EL in the defective sub-pixel BPXL can be disconnected. Then, the anode electrode of the light-emitting element EL can be connected to the repair line 162 via a first welding node W1. The dummy pixel DPXL can be connected to the repair line 162 via second and third welding nodes W2 and W3 and an eighth switch element T8. A current generated from a driving transistor DTD of the dummy pixel DPXL is applied to the anode electrode of the light-emitting element EL of the defective sub-pixel BPXL via the welding node W3 and the repair line 162. For this reason, the light-emitting element EL of the defective sub-pixel BPXL can emit light with target luminance corresponding to a grayscale value of pixel data. The anode reset voltage VAR can be applied to the anode electrode of the light-emitting element EL via the eighth switch element T8 of the dummy pixel DPXL and the third switch element M3 of the defective sub-pixel BPXL.

The pixel circuit of the dummy pixel DPXL includes the driving element DTD, a plurality of switch elements T1 to T8, and capacitors Cst and Cb. In the dummy pixel DPXL, no light-emitting element is required. Each of the fourth and fifth switch elements T4, T51, and T52 can be implemented by an n-channel Oxide TFT. Each of the driving element DTD and the first, second, third, sixth, seventh, and eighth switch elements T1, T2, T3, T6, T7, and T8 can be implemented by a p-channel LTPS TFT.

The pixel circuit of the dummy pixel DPXL is connected to the dummy data line 104 illustrated in FIG. 1 and receives the data voltage of the defective sub-pixel BPXL output from a dummy channel of the data driver 110 via the dummy data line 104. The pixel circuit of the dummy pixel DPXL is connected to the gate lines and the power lines shared by the pixels of the display area AA to receive the same gate signals SC1 to SC4 and EM and the same constant voltages as the pixels of the display area AA.

The driving element DTD includes a gate electrode connected to a first node n21, a first electrode connected to a second node n22, and a second electrode connected to a third node n23.

A first switch element T1 can be connected between the dummy data line and the second node n22. When the first switch element T1 is turned on, the dummy data line can be electrically connected to the second node n22 and the data voltage Vdata can be applied to the second node n22. The first switch element T1 includes a gate electrode connected to the second gate line to which the second scan signal SC2 is applied, a first electrode connected to the dummy data line, and a second electrode connected to the second node n22.

When the second switch element T2 is turned on, the on bias voltage VOBS is applied to the second node n2. The second switch element T2 includes a gate electrode connected to the third gate line to which the third scan signal SC3 is applied, a first electrode connected to the second node n22, and a second electrode connected to the power line to which the on bias voltage VOBS is applied.

When a third switch element T3 is turned on, the second power line PL2 to which the anode reset voltage VAR is applied can be electrically connected to a fifth node n25. The third switch element T3 includes a gate electrode connected to the third gate line to which the third scan signal SC3 is applied, a first electrode connected to the second power line PL2, and a second electrode connected to the fifth node n25.

When a fourth switch element T4 is turned on, the initialization voltage Vinit is applied to the first node n21. The fourth switch element T4 includes a gate electrode connected to the fourth gate line to which the fourth scan signal SC4 is applied, a first electrode connected to the first node n21, and a second electrode connected to the power line to which the initialization voltage Vinit is applied.

When fifth switch elements T51 and T52 are turned on, the first node n21 is electrically connected to the third node n23. The fifth switch elements T51 and T52 can be implemented by dual transistors connected in series between the first node n21 and the third node n23. A fifth-first switch element T51 includes a gate electrode connected to the first gate line to which the first scan signal SC1 is applied, a first electrode connected to the first node n21, and a second electrode connected to a first electrode of a fifth-second switch element T52. The fifth-second switch element T52 includes a gate electrode connected to the first gate line, the first electrode connected to the second electrode of the fifth-first switch element T51, and a second electrode connected to the third node n23.

When a sixth switch element T6 is turned on, the pixel driving voltage ELVDD is applied to the second node n22. The sixth switch element T6 includes a gate electrode connected to the fifth gate line to which the EM signal EM is applied, a first electrode connected to the power line to which the pixel driving voltage ELVDD is applied, and a second electrode connected to the second node n22.

When a seventh switch element T7 is turned on, the third node n23 is electrically connected to a fourth node n24. The seventh switch element T7 includes a gate electrode connected to the fifth gate line to which the EM signal EM is applied, a first electrode connected to the third node n23, and a second electrode connected to the fourth node n24. When the repair step is not performed, the fourth node n24 is not connected to the repair line 162. When the repair step is performed, the metal of the fourth node n24 is welded with a laser beam, passes through the insulating layer, and is connected to the metal of the repair line 162.

When an eighth switch element T8 is turned on, the fifth node n25 can be electrically connected to the repair line 162. The eighth switch element T8 includes a gate electrode connected to the fifth gate line to which the EM signal EM is applied, a first electrode connected to the fifth node n25, and a second electrode connected to the repair line 162.

The storage capacitor Cst is connected between the power line to which the pixel driving voltage ELVDD is applied and the first node n21. A second capacitor Cb is connected between the power line to which the pixel driving voltage ELVDD is applied and the fifth node n25 to charge the anode reset voltage VAR. The structure of the second capacitor Cb can be the substantially same as the storage capacitor Cst, and the capacitance of the second capacitor Cb can also be the same as or similar to the capacitance of the storage capacitor Cst.

According to one or more embodiments of the present disclosure, the display device can be applied to mobile devices, video phones, smart watches, watch phones, wearable device, foldable device, rollable device, bendable device, flexible device, curved device, sliding device, variable device, electronic organizer, electronic books, portable multimedia players (PMPs), personal digital assistants (PDAs), MP3 players, mobile medical devices, desktop PCs, laptop PCs, netbook computers, workstations, navigations, vehicle navigations, vehicle display devices, vehicle devices, theater devices, theater display devices, televisions, wallpaper devices, signage devices, game devices, laptops, monitors, cameras, camcorders, and home appliances, etc. Additionally, the display apparatus according to one or more embodiments of the present disclosure can be applied to organic light emitting lighting devices or inorganic light emitting lighting devices.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and can be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

What is claimed is:

1. A display panel comprising:
a first sub-pixel including a first pixel circuit configured to drive a first light-emitting element;
a second sub-pixel including a second pixel circuit configured to drive a second light-emitting element;
a third sub-pixel including a third pixel circuit configured to drive a third light-emitting element; and
at least one compensation capacitor connected to an anode electrode of one or more of the first light-emitting element, the second light-emitting element, and the third light-emitting element,
wherein the first light-emitting element, the second light-emitting element, and the third light-emitting element are configured to emit light of different wavelengths.

2. The display panel according to claim 1, wherein the at least one compensation capacitor includes:
a first compensation capacitor connected between the anode electrode of the first light-emitting element and a constant voltage node;
a second compensation capacitor connected between the anode electrode of the second light-emitting element and the constant voltage node; and
a third compensation capacitor connected between the anode electrode of the third light-emitting element and the constant voltage node, and
wherein a capacitance of the first compensation capacitor is greater than a capacitance of each of the second compensation capacitor and the third compensation capacitor,
the first light-emitting element is configured to emit red light,
the second light-emitting element is configured to emit green light, and
the third light-emitting element is configured to emit blue light.

3. The display panel according to claim 1, wherein the at least one compensation capacitor includes:
a first compensation capacitor connected between the anode electrode of the first light-emitting element and a constant voltage node;
a second compensation capacitor connected between the anode electrode of the second light-emitting element and the constant voltage node; and
a third compensation capacitor connected between the anode electrode of the third light-emitting element and the constant voltage node, and
wherein a capacitance of the first compensation capacitor is greater than a capacitance of each of the second compensation capacitor and the third compensation capacitor, and
a wavelength of a light emitted by the first light-emitting element is larger than a wavelength of a light emitted by the second light-emitting element, and the wavelength of the light emitted by the second light-emitting element is larger than a wavelength of a light emitted by the third light-emitting element.

4. The display panel according to claim 2, wherein:
the first compensation capacitor, the second compensation capacitor, and the third compensation capacitor are connected in common to a single power line that crosses the first sub-pixel, the second sub-pixel, and the third sub-pixel, and
a constant voltage is applied to the single power line.

5. The display panel according to claim 2, wherein the capacitance of the third compensation capacitor is greater than the capacitance of the second compensation capacitor.

6. The display panel according to claim 1, wherein the at least one compensation capacitor includes:
a first compensation capacitor connected between the anode electrode of the first light-emitting element and a constant voltage node; and
a second compensation capacitor connected between the anode electrode of the third light-emitting element and the constant voltage node, and
wherein a capacitance of the first compensation capacitor is greater than a capacitance of the second compensation capacitor,
the first light-emitting element is configured to emit red light,
the second light-emitting element is configured to emit green light, and
the third light-emitting element is configured to emit blue light.

7. The display panel according to claim 1, wherein:
the at least one compensation capacitor includes a compensation capacitor connected between the anode electrode of the first light-emitting element and a constant voltage node,
the first light-emitting element is configured to emit red light,
the second light-emitting element is configured to emit green light, and
the third light-emitting element is configured to emit blue light.

8. The display panel according to claim 2, wherein:
a constant voltage is applied to the constant voltage node,
each of the first light-emitting element, the second light-emitting element, and the third light-emitting element includes a capacitor, and
a capacitance of the at least one compensation capacitor is smaller than a capacitance of the capacitor of each of the first light-emitting element, the second light-emitting element, and the third light-emitting element.

9. The display panel according to claim 6, wherein:
a constant voltage is applied to the constant voltage node,
each of the first light-emitting element, the second light-emitting element, and the third light-emitting element includes a capacitor, and
a capacitance of the at least one compensation capacitor is smaller than a capacitance of the capacitor of each of the first light-emitting element, the second light-emitting element, and the third light-emitting element.

10. The display panel according to claim 7, wherein:
a constant voltage is applied to the constant voltage node,
each of the first light-emitting element, the second light-emitting element, and the third light-emitting element includes a capacitor, and
a capacitance of the at least one compensation capacitor is smaller than a capacitance of the capacitor of each of the first light-emitting element, the second light-emitting element, and the third light-emitting element.

11. The display panel according to claim 1, wherein each of the first pixel circuit, the second pixel circuit, and the third pixel circuit includes:
a driving transistor including a gate electrode connected to a first node, a first electrode connected to a second node, and a second electrode connected to a third node; and
a storage capacitor connected between a constant voltage node to which a pixel driving voltage is applied and the first node, and
wherein each of the first light-emitting element, the second light-emitting element, and the third light-emitting element includes a capacitor, and
each of a capacitance of the at least one compensation capacitor and a capacitance of the storage capacitor is smaller than a capacitance of the capacitor of each of the first light-emitting element, the second light-emitting element, and the third light-emitting element.

12. The display panel according to claim 11, wherein each of the first pixel circuit, the second pixel circuit, and the third pixel circuit further includes:
a first switch transistor connected between a data line to which a data voltage is applied and the second node, and electrically connecting the data line to the second node when turned on in response to a second scan signal;
a second switch transistor connected between the second node and a first power line to which an on bias voltage is applied, and configured to apply the on bias voltage to the second node when turned on in response to a third scan signal;
a third switch transistor connected between a fourth node to which the anode electrode of the light-emitting element is connected and a second power line to which an anode reset voltage is applied, and configured to apply the anode reset voltage to the fourth node when turned on in response to the third scan signal;
a fourth switch transistor connected between the first node and a fifth power line to which an initialization voltage is applied, and configured to apply the initialization voltage to the first node when turned on in response to a fourth scan signal;
a fifth switch transistor connected between the first node and the third node, and electrically connecting the first node to the third node when turned on in response to a first scan signal;
a sixth switch transistor connected between a third power line to which the pixel driving voltage is applied and the second node, and configured to apply the pixel driving voltage to the second node when turned on in response to a light emission signal; and
a seventh switch transistor connected between the third node and the fourth node, and electrically connecting the third node to the fourth node when turned on in response to the light emission signal, and
wherein the anode electrode of the light-emitting element corresponding to the fourth node is connected to one electrode of the compensation capacitor,
a pixel ground voltage is applied to a cathode electrode of the light-emitting element,
another electrode of the at least one compensation capacitor is connected to the second power line, and
the storage capacitor is connected between the third power line and the first node.

13. The display panel according to claim 12, further comprising:
a dummy pixel that is provided in a non-display area and includes a pixel circuit; and
a repair line that connects the fourth node of a defective sub-pixel among the first sub-pixel, the second sub-pixel, and the third sub-pixel to the pixel circuit of the dummy pixel,
wherein the fourth node of the defective sub-pixel is disconnected, and
the first sub-pixel, the second sub-pixel, and the third sub-pixel are provided in a display area where an image is displayed.

14. A display device comprising:
a display panel including a plurality of data lines, a plurality of dummy data lines, a plurality of gate lines intersecting the plurality of data lines and the plurality of dummy data lines, a plurality of power lines, a plurality of pixels, a plurality of dummy pixels, at least one compensation capacitor, and a gate driving circuit connected to the plurality of gate lines; and
a data driving circuit connected to a data line among the plurality of data lines and a dummy data line among the plurality of dummy data lines,
wherein each of the plurality of pixels includes:
a first sub-pixel including a first pixel circuit configured to drive a first light-emitting element;
a second sub-pixel including a second pixel circuit configured to drive a second light-emitting element;
a third sub-pixel including a third pixel circuit configured to drive a third light-emitting element; and
wherein:
the first light-emitting element, the second light-emitting element, and the third light-emitting element are configured to emit light of different wavelengths,
the at least one compensation capacitor is connected to an anode electrode of one or more of the first light-emitting element, the second light-emitting element, and the third light-emitting element.

15. The display device according to claim 14, wherein the at least one compensation capacitor includes:
a first compensation capacitor connected between the anode electrode of the first light-emitting element and a constant voltage node;
a second compensation capacitor connected between the anode electrode of the second light-emitting element and the constant voltage node; and
a third compensation capacitor connected between the anode electrode of the third light-emitting element and the constant voltage node, and
wherein a capacitance of the first compensation capacitor is greater than a capacitance of each of the second compensation capacitor and the third compensation capacitor,
the first light-emitting element is configured to emit red light,
the second light-emitting element is configured to emit green light, and
the third light-emitting element is configured to emit blue light.

16. The display device according to claim 14, wherein the at least one compensation capacitor includes:
a first compensation capacitor connected between the anode electrode of the first light-emitting element and a constant voltage node;
a second compensation capacitor connected between the anode electrode of the second light-emitting element and the constant voltage node; and
a third compensation capacitor connected between the anode electrode of the third light-emitting element and the constant voltage node, and
wherein a capacitance of the first compensation capacitor is greater than a capacitance of each of the second compensation capacitor and the third compensation capacitor, and
a wavelength of a light emitted by the first light-emitting element is larger than a wavelength of a light emitted by the second light-emitting element, and the wavelength of the light emitted by the second light-emitting element is larger than a wavelength of a light emitted by the third light-emitting element.

17. The display device according to claim 15, wherein:
the first compensation capacitor, the second compensation capacitor, and the third compensation capacitor are connected in common to a single power line that crosses the first sub-pixel, the second sub-pixel, and the third sub-pixel, and
a constant voltage is applied to the single power line.

18. The display device according to claim 14, wherein the at least one compensation capacitor includes:
a first compensation capacitor connected between the anode electrode of the first light-emitting element and a constant voltage node; and
a second compensation capacitor connected between the anode electrode of the third light-emitting element and the constant voltage node, and
wherein a capacitance of the first compensation capacitor is greater than a capacitance of the second compensation capacitor,
the first light-emitting element is configured to emit red light,
the second light-emitting element is configured to emit green light, and
the third light-emitting element is configured to emit blue light.

19. The display device according to claim 14, wherein:
the at least one compensation capacitor includes a compensation capacitor connected between the anode electrode of the first light-emitting element and a constant voltage node,
the first light-emitting element is configured to emit red light,
the second light-emitting element is configured to emit green light, and
the third light-emitting element is configured to emit blue light.

20. The display device according to claim 14, further comprising:
a plurality of repair lines provided in parallel with the plurality of gate lines,
wherein the plurality of pixels are provided in a display area of the display panel where an image is displayed,
the plurality of dummy pixels include pixel circuits provided in a non-display area outside the display area,
a fourth node of a defective sub-pixel among the first sub-pixel, the second sub-pixel, and the third sub-pixel is connected to the pixel circuit of the dummy pixel via the repair line,
the fourth node of the defective sub-pixel is disconnected, and
the first sub-pixel, the second sub-pixel, and the third sub-pixel are provided in the display area.
